(19) United States
(12) Patent Application Publication
(10) Pub. No.: US 2018/0034417 A1
(43) Pub. Date: Feb. 1, 2018

(54) POWER SUPPLY CONTROL

(71) Applicant: QUALCOMM Incorporated, San Diego, CA (US)

(72) Inventors: Joseph DUNCAN, Carlsbad, CA (US); Jongrit LERDWORATAWEE, Santee, CA (US); Song SHI, San Diego, CA (US); Thomas MARRA, San Diego, CA (US)

(21) Appl. No.: 15/644,443

(22) Filed: Jul. 7, 2017

Related U.S. Application Data
(60) Provisional application No. 62/368,921, filed on Jul. 29, 2016.

(51) Int. Cl. H03F 1/02; H03F 3/19; H02M 3/156; G05F 1/46; H03F 3/21; H02M 1/08

(52) U.S. Cl. CPC H03F 1/0216; H03F 3/21; H02M 1/08; H02M 3/156; G05F 1/461; H03F 3/19; H03F 2200/102; H03F 2200/294; H03F 2200/462; H02M 2001/0045

(57) ABSTRACT

Certain aspects of the present disclosure provide methods and apparatus for adjusting voltage regulators of a power supply, such as an envelope tracking power supply. Certain aspects provide a power supply. The power supply may include a first voltage regulator having an output coupled to a voltage supply node of an amplifier. The power supply may further include a second voltage regulator having an output coupled to the voltage supply node of the amplifier. The power supply may further include a controller for adjusting a ratio of an average current supplied by the first voltage regulator to an average current supplied by the second voltage regulator to the voltage supply node of the amplifier based on an output voltage supplied to the voltage supply node of the amplifier by the first voltage regulator and the second voltage regulator.

### CROSS-REFERENCE TO RELATED APPLICATIONS

This application claims the benefit of U.S. Provisional Patent No. 62/368,921, filed Jul. 29, 2016. The content of the provisional application is hereby incorporated by reference in its entirety.

### TECHNICAL FIELD

Certain aspects of the present disclosure generally relate to electronic circuits and, more particularly, to controlling voltage regulators of a power supply.

### BACKGROUND

Wireless communication networks are widely deployed to provide various communication services such as telephony, video, data, messaging, broadcasts, and so on. Such networks, which are usually multiple access networks, support communications for multiple users by sharing the available network resources. For example, one network may be a 3G (the third generation of mobile phone standards and technology), 4G, 5G, or later system, which may provide network service via any one of various radio access technologies (RATs) including EVDO (Evolution-Data Optimized), 1×RTT (1 times Radio Transmission Technology, or simply 1×), W-CDMA (Wideband Code Division Multiple Access), UMTS-TDD (Universal Mobile Telecommunications System—Time Division Duplexing), HSPA (High Speed Packet Access), GPRS (General Packet Radio Service), or EDGE (Enhanced Data rates for Global Evolution). Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, 3^{rd} Generation Partnership Project (3GPP) Long Term Evolution (LTE) networks, and Long Term Evolution Advanced (LTE-A) networks. Other examples of wireless communication networks may include WiFi (in accordance with IEEE 802.11), WiMAX (in accordance with IEEE 802.16), and Bluetooth® networks.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

Amplifiers (e.g., transimpedance amplifiers, inverting amplifiers, etc.) may be used in a variety of systems (which may be referred to as amplification systems) to increase the power of an input signal, including for wireless communication systems. For example, amplifiers may be used in radio frequency (RF) systems, to increase the power of a signal for transmission, or increase the power of a received signal.

Such RF systems may implement envelope tracking, in which the power supply voltage to the amplifier is adjusted so as to roughly track the envelope of a signal for transmission.

### SUMMARY

Certain aspects of the present disclosure provide a power supply. The power supply includes a first voltage regulator having an output coupled to a voltage supply node of an amplifier. The power supply further includes a second voltage regulator having an output coupled to the voltage supply node of the amplifier. The power supply further includes a controller for adjusting a ratio of an average current supplied by the first voltage regulator to an average current supplied by the second voltage regulator to the voltage supply node of the amplifier based on an output voltage supplied to the voltage supply node of the amplifier by the first voltage regulator and the second voltage regulator.

Certain aspects of the present disclosure provide a method for operating a power supply. The method includes adjusting an average current supplied by a first voltage regulator having an output coupled to a voltage supply node of an amplifier based on an output voltage supplied to the voltage supply node of the amplifier by the first voltage regulator and the second voltage regulator. The method further includes adjusting an average current supplied by a second voltage regulator having an output coupled to the voltage supply node of the amplifier based on the output voltage supplied to the voltage supply node of the amplifier by the first voltage regulator and the second voltage regulator, the adjusting the average current supplied by the first voltage regulator and the second voltage regulator comprising adjusting a ratio of the average current supplied by the first voltage regulator to the average current supplied by the second voltage regulator.

Certain aspects of the present disclosure provide a power supply. The power supply includes means for adjusting an average current supplied by a first voltage regulator having an output coupled to a voltage supply node of an amplifier based on an output voltage supplied to the voltage supply node of the amplifier by the first voltage regulator and the second voltage regulator. The power supply further includes means for adjusting an average current supplied by a second voltage regulator having an output coupled to the voltage supply node of the amplifier based on the output voltage supplied to the voltage supply node of the amplifier by the first voltage regulator and the second voltage regulator, the adjusting the average current supplied by the first voltage regulator and the second voltage regulator comprising adjusting a ratio of the average current supplied by the first voltage regulator to the average current supplied by the second voltage regulator.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver/front end, in accordance with certain aspects of the present disclosure.

FIG. 4 illustrates an example envelope tracking amplification system, in accordance with certain aspects of the present disclosure.

FIG. 4A illustrates an example envelope tracking power supply, in accordance with certain aspects of the present disclosure.

FIG. 5 illustrates an example of the current supplied by voltage regulators of an example envelope tracking power supply, in accordance with certain aspects of the present disclosure.

FIG. 6 illustrates an example envelope tracking power supply, in accordance with certain aspects of the present disclosure.

FIG. 6A illustrates an example envelope tracking power supply, in accordance with certain aspects of the present disclosure.

FIG. 7 illustrates example operations for a power supply, in accordance with certain aspects of the present disclosure.

### DETAILED DESCRIPTION

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), and so on. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11, IEEE 802.16, Long Term Evolution (LTE) (e.g., in TDD and/or FDD modes), or some other standards. A TDMA system may implement Global System for Mobile Communications (GSM) or some other standards. These various standards are known in the art.

### An Example Wireless System

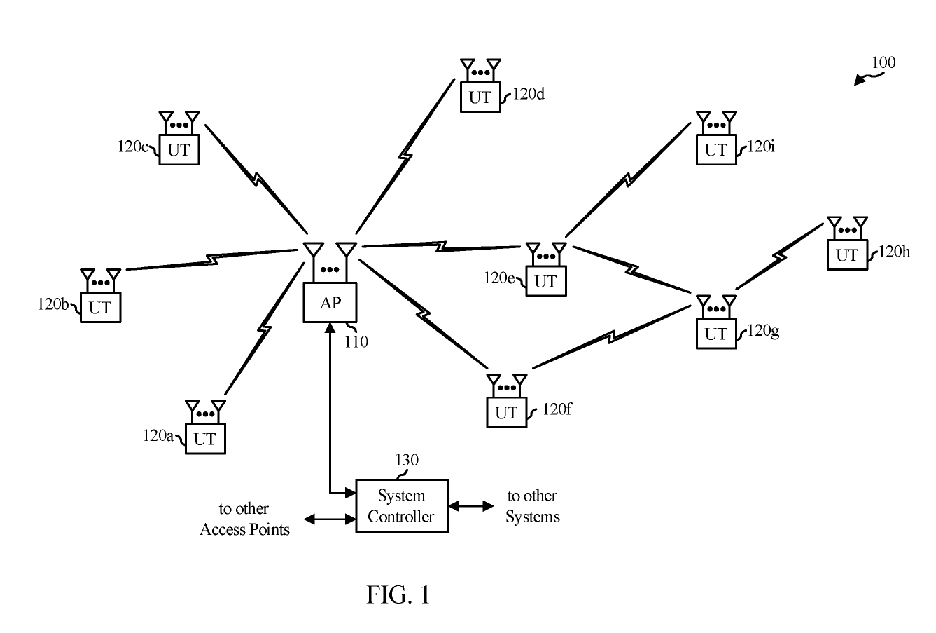

FIG. 1 illustrates a wireless communications system 100 with access points 110 and user terminals 120. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≧1). The Nᵤ selected user terminals can have the same or different number of antennas.

Wireless system 100 may be a time division duplex (TDD) system or a frequency division duplex (FDD) system. For a TDD system, the downlink and uplink share the same frequency band. For an FDD system, the downlink and uplink use different frequency bands. System 100 may also utilize a single carrier or multiple carriers for transmission. Each user terminal 120 may be equipped with a single antenna (e.g., in order to keep costs down) or multiple antennas (e.g., where the additional cost can be supported).

The access point 110 and/or user terminal 120 may include one or more amplifiers to amplify signals for transmission. At least one of the amplifiers may be coupled to a power supply, such as an envelope tracking power supply, designed in accordance with certain aspects of the present disclosure.

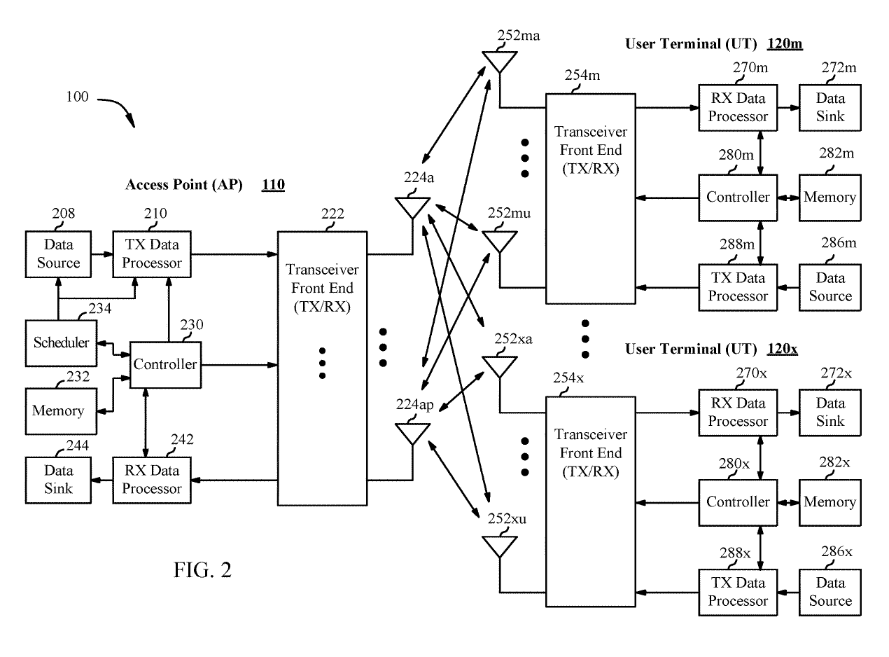

FIG. 2 shows a block diagram of access point 110 and two user terminals 120m and 120x in wireless system 100. In some embodiments, the access point 110 is instead implemented as a base station and/or one or more of the user terminals 120 are instead implemented as a mobile station. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals may be selected for simultaneous transmission on the uplink, N_{dn} user terminals may be selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point, base station, mobile station, and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver/front end (TX/RX) 254 (also known as a radio frequency front end (RFFE)) receives and processes (e.g., converts to analog, amplifies, filters, and frequency upconverts) a respective symbol stream to generate an uplink signal. The transceiver/front end 254 may also route the uplink signal to one of the N_{ut,m} antennas for transmit diversity via an RF switch, for example. The controller 280 may control the routing within the transceiver/front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver/front end 222 may select signals received from one of the antennas 224 for processing. The signals received from multiple antennas 224 may be combined for enhanced receive diversity. The access point's transceiver/front end 222 also performs processing complementary to that performed by the user terminal's transceiver/front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

The transceiver/front end (TX/RX) 222 of access point 110 and/or transceiver/front end 254 of user terminal 120 may include one or more amplifiers to amplify signals for transmission. At least one of the amplifiers may be coupled to a power supply, such as an envelope tracking power supply, designed in accordance with certain aspects of the present disclosure. While FIG. 2 illustrates the transceiver/front ends 222 and 254 each in a single box, those of skill in the art will appreciate that elements of the transceiver/front ends 222, 254 may be implemented across various elements, chips, modules, etc. For example, down and/or upconversion elements may be included in a transceiver chip within the transceiver/front end 222, 254, while a power amplifier and/or envelope tracking elements may be implemented in a module separate from the transceiver chip within the transceiver/front end 222, 254.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol stream for one of more of the N_{dn} user terminals to be transmitted from one of the Nₐₚ antennas. The transceiver/front end 222 receives and processes (e.g., converts to analog, amplifies, filters, and frequency upconverts) the symbol stream to generate a downlink signal. The transceiver/front end 222 may also route the downlink signal to one or more of the Nₐₚ antennas 224 for transmit diversity via an RF switch, for example. The controller 230 may control the routing within the transceiver/front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver/front end 254 may select signals received from one of the antennas 252 for processing. The signals received from multiple antennas 252 may be combined for enhanced receive diversity. The user terminal's transceiver/front end 254 also performs processing complementary to that performed by the access point's transceiver/front end 222 and provides a recovered downlink data symbol stream. An RX data processor 270 processes (e.g., demodulates, deinterleaves, and decodes) the recovered downlink data symbol stream to obtain decoded data for the user terminal.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, TD-SCDMA, and combinations thereof, among other systems/schemes.

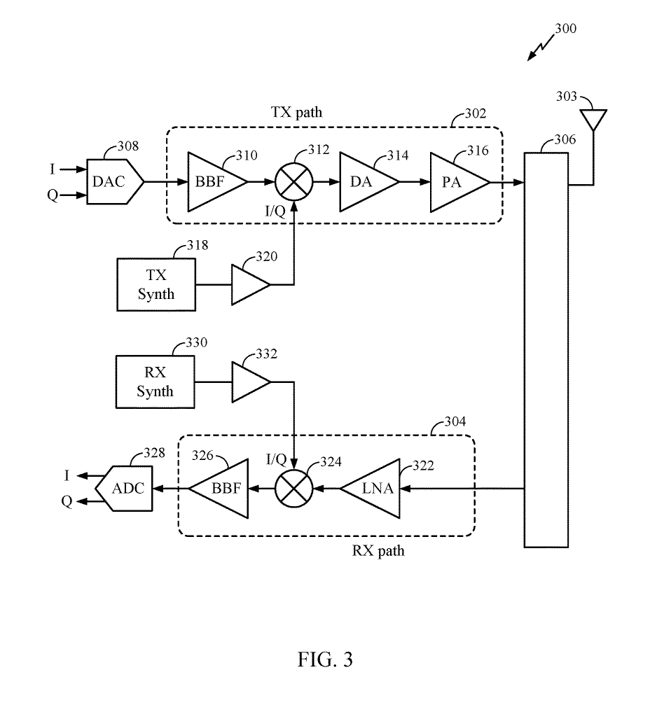

FIG. 3 is a block diagram of an example transceiver/front end 300, such as transceiver/front ends 222, 254 in FIG. 2, in accordance with certain aspects of the present disclosure. The transceiver/front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which are amplified by the DA 314 and by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning to different frequencies indicates using a variable-frequency oscillator, which may involve compromises between stability and tunability. Contemporary systems may employ frequency synthesizers with a VCO to generate a stable, tunable LO with a particular tuning range. Thus, the transmit LO may be produced by a TX frequency synthesizer 318, which may be buffered or amplified by amplifier 320 before being mixed with the baseband signals in the mixer 312. Similarly, the receive LO may be produced by an RX frequency synthesizer 330, which may be buffered or amplified by amplifier 332 before being mixed with the RF signals in the mixer 324. The transceiver/front end 300 may, for example, be configured for operation in quadrature or polar.

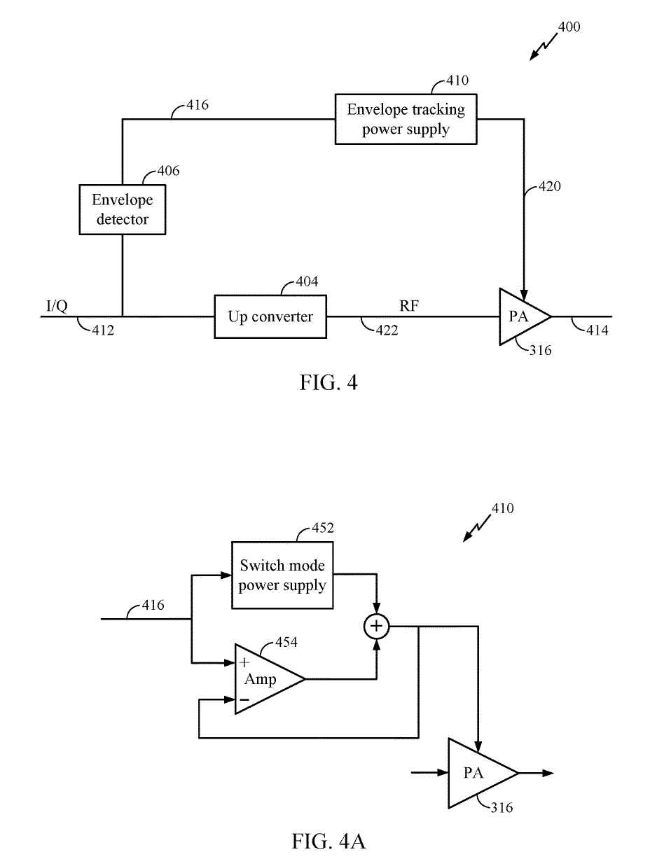

In some aspects, the power supply to the PA 316 may comprise an envelope tracking power supply, in accordance with certain aspects described herein. The envelope tracking supply may be configured to adjust the power supply of the PA 316 such that the power supplied to the PA 316 is based on or substantially tracks the envelope (e.g., envelope waveform) of the signal to be amplified by the PA 316, for example as described in more detail with respect to FIG. 4.

FIG. 4 illustrates an example envelope tracking amplification system 400. The envelope tracking amplification system 400 may include a power amplifier 316, an up-converter 404, an envelope detector 406, and an envelope tracking power supply 410. As illustrated, the amplifier 316 may be configured to amplify an input signal 412. The input signal 412 may represent an in-phase (I) or quadrature-phase (Q) signal (e.g., from the transceiver/front end 300). In some cases, the input signal may form an input to the up-converter 404, which generates an RF input signal 422 for the amplifier 316.

The input signal 412 also forms an input to the envelope detector 406, which generates an envelope signal representing the envelope of the input signal 412 at its output 416 (e.g., provides a signal representing the magnitude of the input signal 412). The output 416 of the envelope detector 406 provides an input to the envelope tracking power supply 410, which in dependence thereon provides a supply voltage 420 to the amplifier 316. Though not shown, in some aspects there may be additional post-processing or pre-distortion applied to the output 416 before being input to the envelope tracking power supply 410. Therefore, the supply voltage 420 of the amplifier is adjusted based on (e.g., tracks) the envelope of the input signal 412. The amplifier 316 generates an amplified output signal 414 based on the input signal 412 (and RF input signal 422). The amplifier 316 may be implemented as a single stage or multi-stage amplifier.

FIG. 4A illustrates an example envelope tracking power supply 410. As shown, the envelope tracking power supply 410 includes a switch mode power supply 452 and an amplifier (e.g., linear regulator, linear amplifier) 454. Each of the switch mode power supply 452 and the amplifier 454 may receive the envelope signal provided on the output 416 and provide power (e.g., current) at a voltage (e.g., at the voltage of supply voltage 420) that is based on the envelope signal. The power of each of the switch mode power supply 452 and the amplifier 454 may be summed to generate the supply voltage 420 to the amplifier 316. In this way, the switch mode power supply 452 and/or the amplifier 454 may be configured to regulate the voltage supplied to the amplifier 316 In some aspects, though not shown, the switch mode power supply 452 may be controlled by a linear amplifier.

In some aspects, the envelope detector 406 may be included in a modem (also referred to as a “baseband processor”). In some aspects, the modem may include one or more of a RX Data Processor 270, a TX Data Processor 288, a DAC 308, and an ADC 328. In some aspects, the modem may include one or more of a RX Data Processor 242, a TX Data Processor 210, a DAC 308, and an ADC 328. In some aspects, the modem may be implemented as a single chip (e.g., integrated circuit). Accordingly, in some aspects, the envelope detector 406 may be implemented in the single chip comprising the modem.

In some aspects, the envelope tracking power supply 410 may be implemented as a single chip (e.g., integrated circuit, such as, an envelope tracking integrated circuit (ETIC)). In some aspects, the envelope detector 406 may be implemented in the same chip as the envelope tracking power supply 410. For example, the envelope tracking power supply may be implemented in a power management IC (PMIC), in a separate chip or module for envelope tracking, or packaged together with the PA 316.

### An Example Power Supply

Certain aspects of the present disclosure generally relate to power supplies. In particular, certain aspects of the present disclosure relate to techniques for operating power supplies, for example to optimize or increase performance of the power supplies. The power supplies may be included in communication devices such as access points or base stations 110 and/or user terminals or mobile stations 120 to provide a supply voltage for amplifiers for wirelessly transmitting signals. In certain aspects, the power supplies presented may be envelope tracking power supplies. In particular, certain aspects are described herein with respect to envelope tracking power supplies. However, it should be noted, that certain aspects described herein may equally apply to other types of power supplies including multiple voltage regulators with a variable output voltage.

In certain aspects, the techniques herein relate to adjusting the level of power (e.g., current) supplied by voltage regulators of a power supply based on an output voltage supplied by the power supply (e.g., an envelope tracking power supply) to an amplifier. In particular, in some aspects, the amount of power (e.g., current, such as, average current) supplied by a first voltage regulator relative to the amount of power (e.g., current, such as, average current) supplied by a second voltage regulator may be based on the output voltage of the power supply. In some aspects, the amount of current (e.g., average current) supplied by a first voltage regulator and the amount of current (e.g., average current) supplied by a second voltage regulator of a power supply is based on the output voltage supply of the power supply relative to an input voltage supply to the voltage regulators of the power supply. In particular, in some aspects, the ratio of current supplied by the first voltage regulator to the amount of current supplied by the second voltage regulator is based on the output voltage relative to the input voltage.

Envelope tracking power supplies have tradeoffs between power conversion efficiency and receive-band noise (RxBN) (e.g., out of band noise generated by a transmitter of a device at a receiver of the device). For example, in FDD LTE operation, a different frequency range may be used by receivers to receive signals than the frequency range used by transmitters to transmit signals. The noise generated by the envelope tracking power supply of a transmitter in a device may be coupled to a receiver of the device, thereby generating RxBN. Accordingly, tradeoffs may be made between power conversion and RxBN for an envelope tracking power supply to avoid de-sensitizing a receiver of the device.

As discussed with respect to FIG. 4A, an envelope tracking power supply may include a first voltage regulator, such as a linear regulator (e.g., linear amplifier), and a second voltage regulator, such as a switch mode power supply (SMPS). In some aspects, a SMPS may be generally more efficient than a linear regulator. However, a linear regulator may produce less noise and have a higher accuracy than a SMPS. For example, the linear regulator may generate a low error vector magnitude (EVM) and further generate a low RxBN. The linear regulator may generate less noise than the SMPS, and therefore less RxBN. Accordingly, in order to balance power conversion efficiency and RxBN of the envelope tracking power supply, the envelope tracking power supply may include both a SMPS and a linear regulator.

In some aspects, the current (I_{SMPS}) generated by the SMPS may have an undesired ripple (e.g., residual periodic variation of the direct current (DC) output of the SMPS). Accordingly, the linear regulator may be operated to cancel the ripple generated by the SMPS. In some examples, such as for low-bandwidth envelope waveforms, where a hysteretic controller is used to control the current output of the SMPS and/or linear regulator, the current sourced/sunk by the linear regulator may mainly be used for cancelling the ripple generated by the SMPS. For example, the average output current of the linear regulator may be approximately 0.

For example, the linear regulator may source additional current (I_{LR}) to the output of the SMPS or sink current (I_{LR}) generated by the SMPS to cancel the ripple generated by the SMPS. The overall current (I_{LOAD}) to the amplifier from the envelope tracking power supply, therefore, may be a sum of I_{SMPS} and I_{LR} (I_{SMPS}+I_{LR}=I_{LOAD}). The average current of the SMPS may be set to approximately I_{LOAD}, while the average current of the linear regulator may be set to approximately 0. Therefore, the overall combined output of the SMPS and the linear regulator may be a substantially DC output at I_{LOAD} in certain circumstances.

In some aspects, increasing a switching frequency of the SMPS may reduce the ripple created and the ripple cancellation loss, thereby increasing power conversion efficiency, but may increase RxBN, especially at low-duplexes where the transmit band and receive band are close in frequency. Accordingly, some aspects herein provide techniques for adjusting the amount of current (e.g., average current) supplied by a SMPS, and accordingly the amount of current sourced/sunk by a linear regulator (e.g., the average current supplied by the linear regulator), which may increase power conversion efficiency of the envelope tracking power supply, while maintaining low RxBN. In particular, certain aspects provide techniques for adjusting the ratio of current supplied by the SMPS to the current supplied by the linear regulator.

In some aspects, power conversion efficiency of a voltage regulator can be described as the amount of input current used by a voltage regulator to produce a desired output current by the voltage regulator. For example, the voltage regulators may be coupled to a power supply (e.g., battery, boost converter, etc.) that provides power (e.g., current) to the voltage regulators. In some aspects, the power may be provided at a voltage level (V_{IN}). For a linear regulator, the input current (I_{LR}_{_}_{IN}) to the linear regulator needed to produce an output current (I_{LR}) of the linear regulator is approximately equal to the output current (e.g., I_{LR}_{_{−}}_{IN}˜I_{LR}). For a SMPS, the input current (I_{SMPS}_{_}_{IN}) to the SMPS needed to produce an output current (I_{SMPS}) of the SMPS is based on the losses of the SMPS and proportional to the output voltage (V_{OUT}) of the SMPS relative to the input voltage (V_{IN}) to the SMPS (e.g., I_{SMPS}_{_}_{IN}˜(V_{OUT}/V_{IN})*I_{SMPS}+Losses). Accordingly, the power conversion efficiency of the linear regulator is not based on the output voltage of the linear regulator, but the power conversion efficiency of the SMPS is based on the output voltage of the SMPS. Accordingly, as V_{OUT}/V_{IN} for the SMPS approaches 1 (i.e., V_{OUT} approaches V_{IN}), power conversion efficiency advantage of the SMPS over the linear regulator may be lost, as the power conversion efficiency approaches that of the linear regulator. However, as V_{OUT}/V_{IN} approaches ground (e.g., 0) (i.e., V_{OUT} is lower than V_{IN}), the SMPS may have a power conversion efficiency advantage over the linear regulator.

Accordingly, in certain aspects, the amount of current (e.g., average current) I_{SMPS} supplied by the SMPS of the envelope tracking power supply is controlled based on V_{OUT}/V_{IN}. Further, since the total current I_{LOAD} supplied by the envelope tracking power supply is the sum of I_{SMPS} and I_{LR}, the amount of current (e.g., average current) I_{LR} supplied by the linear regulator is based on I_{SMPS} and, therefore controlled based on V_{OUT}/V_{IN}. In particular, a controller (e.g., modem) may determine V_{OUT}/V_{IN} and control the amount of current output by each of the SMPS and the linear regulator. For example, as the envelope for a signal to be amplified increases closer to the V_{IN} of a power supply, the required V_{OUT} from the envelope tracking power supply increases closer to V_{IN} and the amount of current (e.g., average current) I_{SMPS} supplied by the SMPS decreases. Accordingly, the amount of current I_{LR} sourced from the linear regulator increases and the amount of current I_{LR} sunk by the linear regulator decreases, meaning the average current I_{LR} supplied by the linear regulator increases. Accordingly, the ratio of current I_{SMPS} to I_{LR} decreases. As the envelope for a signal to be amplified decreases away from the V_{IN} of a power supply, the required V_{OUT} from the envelope tracking power supply decreases away from V_{IN} and the amount of current I_{SMPS} supplied by the SMPS increases. Accordingly, the amount of current I_{LR} sourced from the linear regulator decreases and the amount of current I_{LR} sunk by the linear regulator increases, meaning the average current I_{LR} supplied by the linear regulator decreases. Accordingly, the ratio of current I_{SMPS} to I_{LR} increases.

In some aspects, the amount of current (e.g., average current) I_{SMPS} supplied by the SMPS (and accordingly the amount of current supplied by the linear regulator) may be directly proportional to V_{OUT}/V_{IN}. In some aspects, the amount of current (e.g., average current) I_{SMPS} supplied by the SMPS (and accordingly the amount of current supplied by the linear regulator) may be fixed for particular ranges of V_{OUT}/V_{IN}. For example, there may be a threshold V_{OUT}/V_{IN} where the power conversion efficiency of the SMPS is equal to the power conversion efficiency of the linear regulator. For any V_{OUT}/V_{IN} above the threshold (e.g., approaching 1) the linear regulator may be used to supply a positive average current to the amplifier. For any V_{OUT}/V_{IN} below the threshold (e.g., approaching 0) the SMPS may be used to supply power to the amplifier, with the linear regulator being used to cancel the ripple of the SMPS and potentially supply a negative average current to the amplifier. The amount of current (e.g., average current) supplied by the SMPS may be controlled by a controller (e.g., modem) of a device that includes the envelope tracking power supply. Further, the amount of current (e.g., average current) sunk/sourced by the linear regulator may be based on the amount of current supplied by the SMPS to eliminate ripple and provide a DC output at the desired current. For example, in certain aspects, an input of the linear regulator is coupled to a feedback path from the output of the envelope tracking power supply and adjusts the current sunk/sourced to eliminate any ripple in the output and provide the desired current. In some aspects, the linear regulator may also be controlled by the controller.

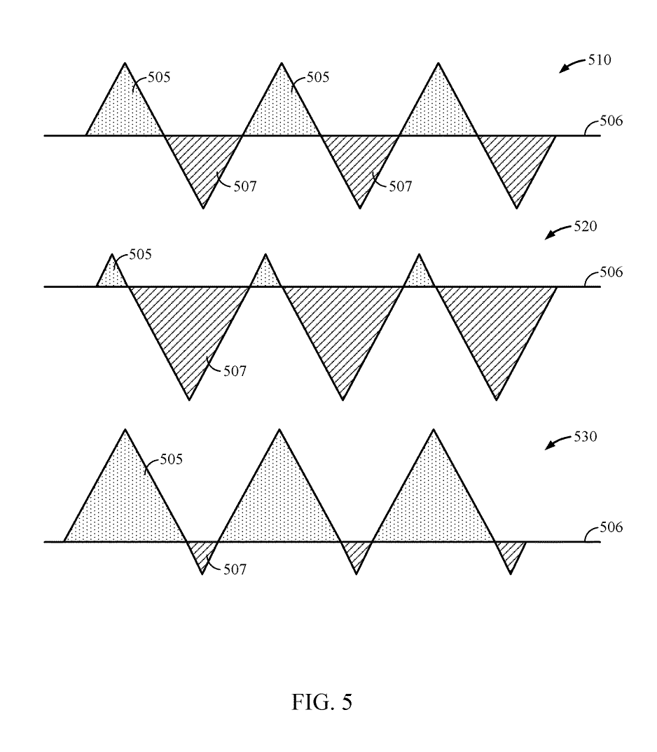

FIG. 5 illustrates an example of the benefit of supplying current by the SMPS relative to V_{OUT}/V_{IN} according to certain implementations described herein. In particular, line 510 illustrates a case where the current supplied by the SMPS is not based on the output voltage of the envelope tracking power supply relative to the input supply voltage to the SMPS. Alternatively, the line 510 may illustrate a case where the current supplied by the SMPS is based on the output voltage of the envelope tracking power supply relative to the input supply voltage to the SMPS, where the optimal average output current from the SMPS is determined to be I_{LOAD}. The straight horizontal line 506 represents the average output current I_{LOAD} of the power supply. The triangles 505 and 507 are indicative of the ripple in I_{SMPS} relative to I_{LOAD}. Accordingly, the triangles 505 represent excess current supplied by the SMPS. This excess current is then sunk by the linear regulator. The triangles 507 represent the current sourced by the linear regulator to account for times when the current I_{SMPS} is below the desired I_{LOAD}. As shown in line 510 by the positions of triangles 505 and 507 with respect to I_{LOAD} line 506, the current I_{SMPS} supplied by the SMPS is centered around the output current I_{LOAD} delivered to the power amplifier by the envelope tracking power supply.

Line 520 illustrates a case where the current supplied by the SMPS is based on the output voltage of the envelope tracking power supply relative to the input supply voltage to the SMPS. In particular, line 520 represents a case where V_{OUT}/V_{IN} is high (e.g., close to 1). As shown in line 520 by the positions of triangles 505 and 507 with respect to I_{LOAD} line 506, the current I_{SMPS} supplied by the SMPS is centered (averaged) below the output current I_{LOAD} delivered to the power amplifier by the envelope tracking power supply. In particular, since V_{OUT}/V_{IN} is high it may be more efficient for the linear regulator to supply more current I_{LR} and sink less of the current I_{SMPS} to attain the desired I_{LOAD}. Accordingly, the linear regulator may supply a positive average current I_{LR}.

Line 530 illustrates a case where the current supplied by the SMPS is based on the output voltage of the envelope tracking power supply relative to the input supply voltage to the SMPS. In particular, line 530 represents a case where V_{OUT}/V_{IN} is low (e.g., close to 0). As shown in line 530 by the positions of triangles 505 and 507 with respect to I_{LOAD} line 506, the current I_{SMPS} supplied by the SMPS is centered (averaged) above the output current I_{LOAD} delivered to the power amplifier by the envelope tracking power supply. In particular, since V_{OUT}/V_{IN} is low it may be more efficient for the linear regulator to supply less current I_{LR} and sink more of the current I_{SMPS} to attain the desired I_{LOAD}. Accordingly, the linear regulator may supply a negative average current I_{LR}.

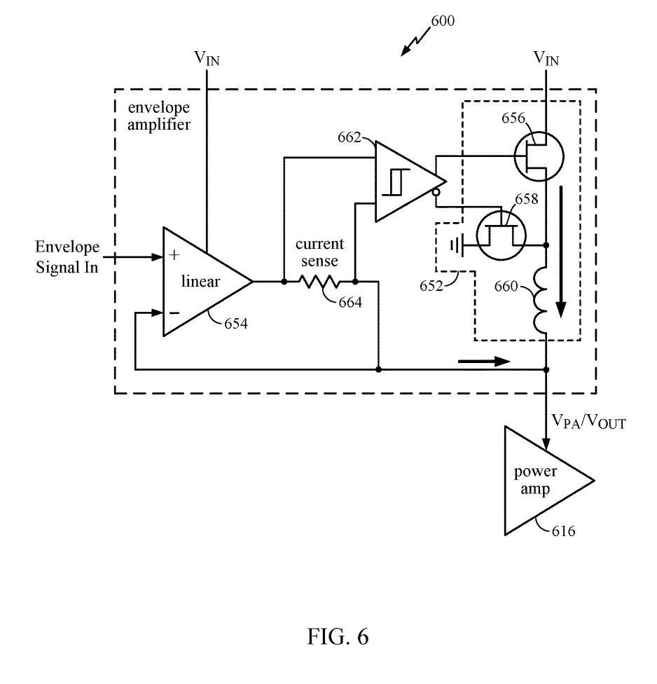

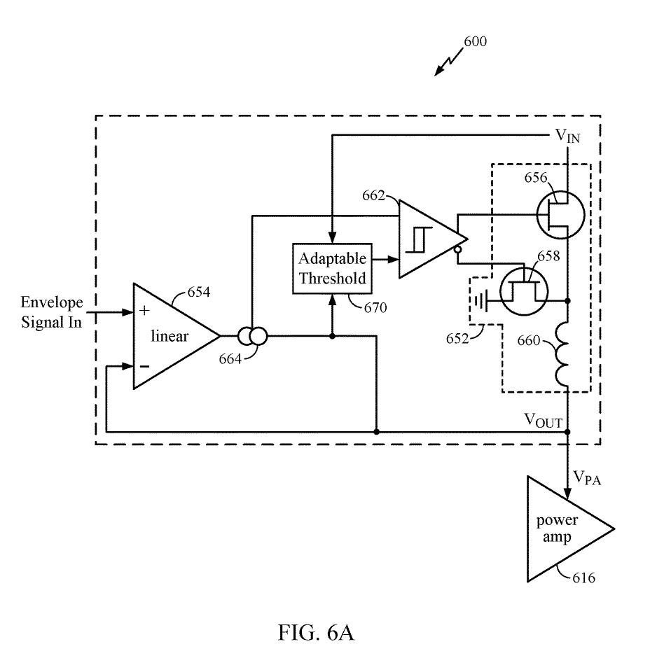

FIG. 6 illustrates an example envelope tracking power supply 600 that may implement the techniques discussed herein. As shown, the envelope tracking power supply 600 is coupled to and supplies an output voltage V_{OUT} to a power amplifier 616 (e.g., PA 316). The envelope tracking power supply 600 includes a linear regulator 654 and a SMPS 652, and may be implementation of the envelope tracking power supply 410 described with respect to FIGS. 4 and 4A.

The SMPS 652 includes a first transistor 656, a second transistor 658, and an inductor 660. The SMPS 652 is coupled to a power supply and receives power at a voltage V_{IN}. The linear regulator 654 is also coupled to a power supply (e.g., the same power supply or a different power supply) and receives power at a voltage V_{IN} (or at a different voltage than the SMPS 652; while illustrated as V_{IN} in FIG. 6, the linear regulator 654 may receive a different voltage, for example a boosted voltage). Each of the SMPS 652 and linear regulator 654 are configured to generate current, as discussed herein, at the voltage V_{OUT}. In particular, V_{OUT} may be based on the envelope of a signal to be amplified by the amplifier 616. As discussed herein, the average current supplied by each of the linear regulator 654 and the SMPS 652 may be based on V_{OUT}/V_{IN}. In particular, a controller (e.g., modem) may be configured to adjust a target current (e.g., average current) of the regulator 654 and SMPS 652. In some aspects, the controller may be implemented within the power supply 600, or a controller local to the power supply 600 may receive information or instructions from the modem and adjust the SMPS 652 and the linear regulator 654 appropriately.

The linear regulator 654 is configured to receive a signal indicative of the envelope of the signal to be amplified by the amplifier 616. The linear regulator 654 may adjust the output voltage V_{OUT} of the linear regulator 654 based on the received envelope signal. The linear regulator 654 may further be coupled to a feedback path from the output of the envelope tracking power supply (the combined output of the SMPS 652 and the linear regulator 654) that the linear regulator 654 uses to adjust the output voltage of the linear regulator 654 to match the V_{OUT} based on the envelope signal.

The envelope tracking power supply may further include a current sensing circuit 664 that senses the current output of the linear regulator 654. The sensed current may be input to a comparator 662, which has an output coupled to the gates of the transistors 656 and 658 of the SMPS 652, and thus may control the voltage regulation of the SMPS 652. In particular, the comparator 662 may control the voltage output of the SMPS 652 to match the voltage output of the linear regulator 654. In some embodiments, the current sensing circuit 664 and/or the comparator 662 are implemented in the controller of the power supply 600.

FIG. 6A illustrates another embodiment of the envelope tracking power supply 600. In particular, the envelope tracking power supply 600 in FIG. 6A, in addition to the embodiment shown in FIG. 6, also includes an adaptable threshold component 670. The adaptable threshold component 670 may be a controller configured to adjust a target current (e.g., average current) of the SMPS 652 (and/or the linear regulator 654). The adaptable threshold component 670 may be implemented in a modem (e.g., outside of the power supply 600), a separate controller, within the power supply 600 as illustrated, etc. The adaptable threshold component 670 is configured to receive information about V_{IN} and V_{OUT} and supply a signal to the comparator 662 based on V_{IN} and V_{OUT}. In particular, in some aspects, the signal generated by the adaptable threshold component 670 may cause the comparator 662 to adjust the current supplied by the SMPS 652 (including controlling a switching frequency of the SMPS 652, controlling a duration of the on/off times of transistors 656 and 658, etc.) based on V_{OUT}/V_{IN} as discussed herein. In some aspects, the adaptable threshold component 670 may adjust the current supplied by the SMPS 652 based on the current supplied by the linear regulator 654. In some aspects, the signal generated by the adaptable threshold component 670 may cause the comparator 662 to adjust the voltage supplied by the SMPS 652 to be V_{OUT}.

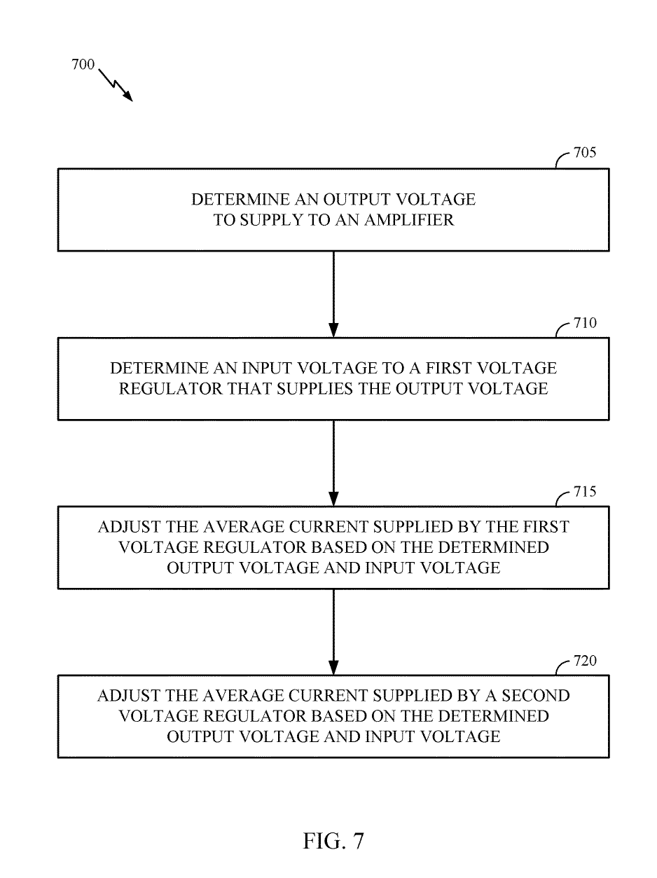

FIG. 7 illustrates example operations 700 for a power supply, in accordance with certain aspects of the present disclosure.

At 705, an output voltage to supply to an amplifier is determined. For example, the power supply may be an envelope tracking power supply such as the power supply 600, and the output voltage may be determined (e.g., by the linear regulator 654) based on an envelope of a signal to be amplified by the amplifier (e.g., the power amplifier 316 or 616). For example, the envelope tracking power supply may determine the output voltage based on the envelope or a signal indicative thereof received from a modem.

At 710, an input voltage to a first voltage regulator of the power supply is determined. For example, the power supply may have information regarding the voltage or sense the voltage of a power supply to the first voltage regulator (e.g., the adaptable threshold component 670 component may be provided with or sense the voltage, for example V_{IN}, provided to the SMPS 652).

At 715, the average current supplied by the first voltage regulator is adjusted based on the determined output voltage (e.g., by a controller in the power supply 600 or external to the power supply 600, or by the adaptable threshold component 670 and/or comparator 662, which may comprise or be implemented in the controller). For example, the average current supplied by the first voltage regulator may be set based on the ratio of the determined output voltage to the determined input voltage. The average current may be set higher (e.g., above a desired current to supply to the amplifier) where the ratio is closer to 0, and the average current may be set lower (e.g., below a desired current to supply to the amplifier) where the ratio is closer to 1.

At 720, the average current supplied by a second voltage regulator (e.g., the linear regulator/amplifier 654) is adjusted based on the determined output voltage (e.g., by a controller in the power supply 600 or external to the power supply 600, or by the adaptable threshold component 670 and/or comparator 662, which may comprise or be implemented in the controller). For example, the average current supplied by the second voltage regulator may be set based on the ratio of the determined output voltage to the determined input voltage, or the average current supplied by the first voltage regulator. The average current may be set lower (e.g., below a desired current to supply to the amplifier) where the ratio is closer to 0, and the average current may be set higher (e.g., above a desired current to supply to the amplifier) where the ratio is closer to 1. Accordingly, the sum of the average current of the first voltage regulator and the second voltage regulator may be set at the desired current to supply to the amplifier. Further, accordingly, the ratio of the average current of the first voltage regulator to the average current of the second voltage regulator is adjusted.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. An apparatus, comprising:
a first voltage regulator having an output coupled to a voltage supply node of an amplifier;
a second voltage regulator having an output coupled to the voltage supply node of the amplifier; and
a controller configured to adjust a ratio of an average current supplied by the first voltage regulator to an average current supplied by the second voltage regulator to the voltage supply node of the amplifier based on an output voltage supplied to the voltage supply node of the amplifier by the first voltage regulator and the second voltage regulator.

2. The apparatus of claim 1, wherein the first voltage regulator comprises a switch mode power supply, and wherein the second voltage regulator comprises a linear regulator.

3. The apparatus of claim 2, wherein the average current supplied by the switch mode power supply decreases and the average current supplied by the linear regulator increases as the output voltage increases.

4. The apparatus of claim 2, wherein the linear regulator is coupled to a feedback path from the voltage supply node of the amplifier, the linear regulator being configured to adjust for a ripple current of the switch mode power supply based on a signal on the feedback path.

5. The apparatus of claim 1, wherein the output voltage supplied to the voltage supply node of the amplifier is based on an envelope of an input signal to the amplifier.

6. The apparatus of claim 1, wherein the average current supplied by the first voltage regulator to the voltage supply node of the amplifier is further based on the output voltage relative to an input voltage to the first voltage regulator.

7. The apparatus of claim 6, wherein the first voltage regulator comprises a switch mode power supply, wherein the second voltage regulator comprises a linear regulator, and wherein the controller is configured to compare a ratio of the output voltage relative to the input voltage to a threshold and set the average current of the linear regulator above 0 when the threshold is satisfied.

8. The apparatus of claim 6, wherein the first voltage regulator comprises a switch mode power supply, wherein the second voltage regulator comprises a linear regulator, and wherein the controller is configured to compare a ratio of the output voltage relative to the input voltage to a threshold and set the average current of the linear regulator to 0 or below when the threshold is not satisfied.

9. The apparatus of claim 1, wherein the first voltage regulator is coupled to a first power supply, and wherein the second voltage regulator is coupled to a second power supply.

10. The apparatus of claim 9, wherein the first power supply and the second power supply are the same power supply.

11. The apparatus of claim 1, further comprising:
a current sensing circuit configured to sense a current output of the second voltage regulator; and
a comparator configured to receive an input indicative of the current output of the second voltage regulator from the current sensing circuit and control a voltage output of the first voltage regulator to match a voltage output of the second voltage regulator.

12. A method for operating a power supply, comprising:
adjusting an average current supplied by a first voltage regulator having an output coupled to a voltage supply node of an amplifier based on an output voltage supplied to the voltage supply node of the amplifier by the first voltage regulator and a second voltage regulator; and
adjusting an average current supplied by the second voltage regulator having an output coupled to the voltage supply node of the amplifier based on the output voltage supplied to the voltage supply node of the amplifier by the first voltage regulator and the second voltage regulator, the adjusting the average current supplied by the first voltage regulator and the second voltage regulator comprising adjusting a ratio of the average current supplied by the first voltage regulator to the average current supplied by the second voltage regulator.

13. The method of claim 12, wherein the first voltage regulator comprises a switch mode power supply, and wherein the second voltage regulator comprises a linear regulator.

14. The method of claim 13, wherein the average current supplied by the switch mode power supply decreases and the average current supplied by the linear regulator increases as the output voltage increases.

15. The method of claim 13, wherein the linear regulator is configured to adjust for a ripple current of the switch mode power supply.

16. The method of claim 12, wherein the output voltage supplied to the voltage supply node of the amplifier is based on an envelope of an input signal to the amplifier.

17. The method of claim 12, wherein the average current supplied by the first voltage regulator to the voltage supply node of the amplifier is further based on the output voltage relative to an input voltage to the first voltage regulator.

18. The method of claim 17, wherein the first voltage regulator comprises a switch mode power supply, and wherein the second voltage regulator comprises a linear regulator, the method further comprising comparing a ratio of the output voltage relative to the input voltage to a threshold and setting the average current of the linear regulator above 0 when the threshold is satisfied.

19. The method of claim 17, wherein the first voltage regulator comprises a switch mode power supply, and wherein the second voltage regulator comprises a linear regulator, the method further comprising comparing a ratio of the output voltage relative to the input voltage to a threshold and setting the average current of the linear regulator to 0 or below when the threshold is not satisfied.

20. The method of claim 12, wherein the first voltage regulator is coupled to a first power supply, and wherein the second voltage regulator is coupled to a second power supply.

21. The method of claim 20, wherein the first power supply and the second power supply are the same power supply.

22. The method of claim 12, further comprising:
sensing a current output of the second voltage regulator; and
controlling a voltage output of the first voltage regulator to match a voltage output of the second voltage regulator based on the sensed current output of the second voltage regulator.

23. A power supply, comprising:
means for adjusting an average current supplied by a first voltage regulator having an output coupled to a voltage supply node of an amplifier based on an output voltage supplied to the voltage supply node of the amplifier by the first voltage regulator and a second voltage regulator; and
means for adjusting an average current supplied by the second voltage regulator having an output coupled to the voltage supply node of the amplifier based on the output voltage supplied to the voltage supply node of the amplifier by the first voltage regulator and the second voltage regulator, the adjusting the average current supplied by the first voltage regulator and the second voltage regulator comprising adjusting a ratio of the average current supplied by the first voltage regulator to the average current supplied by the second voltage regulator.

24. The power supply of claim 23, wherein the first voltage regulator comprises a switch mode power supply, and wherein the second voltage regulator comprises a linear regulator.
